(19) United States
(12) Patent Application Publication
(10) Pub. No.: US 2008/0057726 A1
(43) Pub. Date: Mar. 6, 2008

(54) Apparatus and method for fabricating semiconductor device and removing by-products

(75) Inventor: In Jun Kim, Dong-gu (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU HITEK CO., LTD.

(21) Appl. No.: 11/892,754

(22) Filed: Aug. 27, 2007

(30) Foreign Application Priority Data
Aug. 29, 2006 (KR) 10-2006-0082398

(51) Int. Cl. H01L 21/461; C25F 1/00; H01L 21/306

(52) U.S. Cl. 438/711; 134/1.2; 156/345.29; 257/E21.483

(57) ABSTRACT

An apparatus and a method for fabricating a semiconductor device are provided. The method can efficiently remove by-products from a foreline connected to a process chamber. The apparatus includes a remote plasma source, which generates a plasma gas. The plasma gas is guided to the foreline, so as to remove impurities formed on an inner wall of the foreline.

The present application claims the benefit of priority under 35 U.S.C. §119 to Korean Patent Application No. 10-2006-0082398 (filed on Aug. 29, 2006), the entire contents of which are incorporated herein by reference.

### BACKGROUND

1. Technical Field

The present invention relates to a method and an apparatus for fabricating a semiconductor device. More specifically, the present invention relates to a method and an apparatus for fabricating a semiconductor device, and for efficiently removing by-products from a foreline to improve fabrication yield of the semiconductor device.

2. Related Art

Generally, by-products and/or active chemical species generated in a process chamber, where various processes may be performed, are exhausted through a foreline connected to the chamber. In the related art, the foreline may be made of a metallic material, such as aluminum (Al), stainless steel, etc. However, for such a metallic foreline, after a process, such as an etch process, is performed in the process chamber, the by-products from the process chamber may be deposited on an inner wall of the foreline. The by-products deposited on the foreline may cause various problems during processes performed in the process chamber.

For example, the by-products deposited on the inner wall of the foreline may flow back to the process chamber due to an abnormal pressure generated in the foreline or the process chamber. Accordingly, the by-products may reduce the flow rate through the foreline. Also, such by-products may have an effect on a vacuum pump for evacuating exhaust gas, such that an effective lifetime of the vacuum pump may be shortened.

Various attempts have been made in order to solve these problems. Among the attempts, a method has been developed for preventing etching by-products from being deposited on the inner wall of the foreline by installing a heating jacket on an external surface of the foreline, and a method for performing various coatings for effectively preventing the by-products from being deposited on the inner wall of the foreline.

Although the heating jacket may prevent the by-products from being deposited on the inner wall of the foreline, however, the price of the heating jacket may be expensive and the lifetime of the heating jacket may be short. Also, the method of coating the inner wall of the foreline may not prevent the deposition of the by-products in an effective manner.

### SUMMARY

In one embodiment, there is provided an apparatus for fabricating a semiconductor device. The apparatus includes: a process chamber where for performing a wafer processing step process is performed; a foreline connected to the process chamber for evacuating exhausting exhaust gas from the process chamber; and a remote plasma source connected to the foreline, the remote plasma source and supplying plasma gas to the foreline for cleaning the inside an inner wall of the foreline.

In another embodiment, there is provided a method for fabricating a semiconductor device. The method includes: performing a wafer processing process step in a process chamber; exhausting evacuating an exhaust gas generated from the process chamber through a foreline; and cleaning the foreline by inletting providing a plasma gas generated from a remote plasma source connected to the foreline to the foreline.

### BRIEF DESCRIPTION OF THE DRAWINGS

FIG. 1 is a block diagram illustrating an apparatus for fabricating a semiconductor device consistent with the present invention; and

FIG. 2 is a block diagram illustrating a remote plasma source in an apparatus for fabricating a semiconductor device consistent with the present invention.

### DETAILED DESCRIPTION

Hereinafter, an apparatus for fabricating a semiconductor device consistent with the present invention will be described in detail with reference to the accompanying drawings.

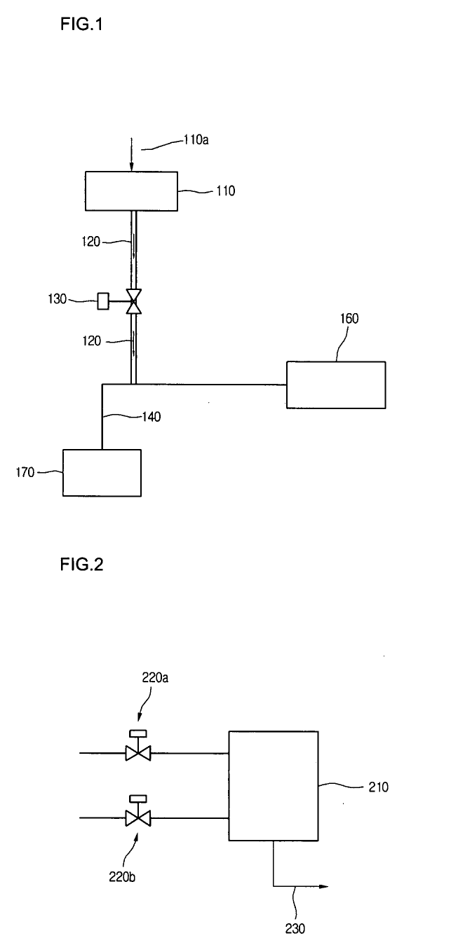

As shown in FIG. 1, the apparatus may comprise a chamber 170, where a semiconductor processing step may be performed; a foreline 140 for evacuating an exhaust gas; a pump 160 for evacuating the exhaust gas via foreline 140 from chamber 170.

The apparatus may further comprise a remote plasma source 110 for providing plasma gas to foreline 140. Remote plasma source 110 may generate plasma by various means, for example, by using radio frequency electromagnetic waves. Remote plasma source 110 may comprise a gas inlet line 110a to provide a source gas to remote plasma source 110, and a plasma inlet line 120 to provide the plasma gas generated from remote plasma source 110 to foreline 140.

In one embodiment, the source gas may react with the by-products formed on the inner wall of foreline 140 to remove the by-products. For example, if the by-products formed on the inner wall of foreline 140 are plasma-based, the plasma gas may include ozone (O₃) plasma. Accordingly, in order to generate the ozone plasma, oxygen or a gas mixture of oxygen and nitrogen, etc., should be provided to remote plasma source 110. For example, if the by-products formed on the inner wall of foreline 140 are an insulator or silicon (Si) based, the plasma gas may include fluorine (F). Accordingly, a gas such as NF₃, CF₄, CF₄+O₂, etc., can be used as the source gas of remote plasma source 110.

The apparatus for fabricating the semiconductor device may further comprise a valve unit 130 provided between remote plasma source 110 and foreline 140. Valve unit 130 may interrupt or control the plasma gas or the amount thereof provided from remote plasma source 110 to foreline 140 according to process conditions.

In one embodiment, remote plasma source 110 may be connected to chamber 170, so as to provide a process gas required for the process performed in chamber 170 and to provide the plasma gas for removing the by-products. In one embodiment, remote plasma source 110 may be separated from the apparatus for fabricating the semiconductor device, so as to only provide the plasma gas for removing the by-products.

As shown in FIG. 2, in one embodiment, a remote plasma source 210 may comprise mass flow controllers (MFC) 220a and 220b to control a flow speed of gas for generating the plasma guided into an inlet line for inletting a process gas to remote plasma source 210 in order to generate the plasma. Although two MFCs are shown in FIG. 2, it is appreciated that remote plasma source 210 may comprise a different number of MFCs depending on the type of inlet gas to be used.

According to another embodiment, a method for fabricating a semiconductor device using the fabricating apparatus described above is provided. Referring to FIG. 1, a wafer processing step may be performed in process chamber 170. In one embodiment, process chamber 170 may be a plasma etch chamber.

When the wafer processing step in process chamber 170 is completed, exhaust gas generated from process chamber 170 may be evacuated to the environment through foreline 140 connected to process chamber 170. After all the exhaust gas is evacuated, process chamber 170 is in an idle state. At this time, the plasma gas is generated from remote plasma source 110 connected to foreline 140 and the plasma gas is provided to foreline 140. Thereafter, a cleaning step may be performed to remove impurities formed in foreline 140 by using the plasma gas.

It is to be understood that the process order described above may be changed. For example, the step of cleaning foreline 140 may be performed together with the semiconductor wafer processing step in chamber 170. That is, when performing the wafer processing step in chamber 170, the plasma gas may be guided from remote plasma source 110 to foreline 140, so that the cleaning process may be performed to remove the impurity formed on the inner wall of foreline 140.

As described above, various kinds of the plasma gas can be used depending on the type of impurities formed on the inner wall of foreline 140. Therefore, the plasma gas can remove the by-products deposited on the inner wall of foreline 140, so that problems generated by the by-products can be solved.

The apparatus and the method for fabricating the semiconductor device consistent with the present invention can effectively remove the by-products formed on the inner wall of foreline 140, thereby improving the process reliability and the fabrication yield, and reducing the process time.

Although embodiments consistent with the present invention have been described with reference to a number of illustrative embodiments thereof, it should be understood that numerous other modifications and variations can be devised by those skilled in the art. More particularly, various variations and modifications are possible in the component parts and/or arrangements of the subject combination arrangement. In addition to variations and modifications in the component parts and/or arrangements, alternative uses will also be apparent to those skilled in the art.

What is claimed is:

1. An apparatus for fabricating a semiconductor device, comprising:
a process chamber for performing a wafer processing step;
a foreline connected to the process chamber for evacuating exhaust gas from the process chamber; and
a remote plasma source connected to the foreline, the remote plasma source supplying plasma gas to the foreline for cleaning an inner wall of the foreline.

2. The apparatus according to claim 1, wherein the remote plasma source is connected to the process chamber through the foreline.

3. The apparatus according to claim 1, wherein the plasma gas comprises an ozone gas or a fluorine gas.

4. The apparatus according to claim 1, further comprising a first valve unit disposed between the foreline and an inlet line connected to the remote plasma source, the first valve unit controlling an amount of the plasma gas through the inlet line from the remote plasma source to the process chamber.

5. The apparatus according to claim 1, wherein the remote plasma source comprises:
an inlet line for providing a source gas to the remote plasma source; and
a plurality of second valve units disposed in the inlet line, the second valve units controlling the source gas flux.

6. A method for fabricating a semiconductor device, comprising:
performing a wafer processing step in a process chamber;
evacuating an exhaust gas from the process chamber through a foreline; and
cleaning the foreline by providing a plasma gas from a remote plasma source to the foreline.

7. The method according to claim 6, wherein cleaning the foreline is performed at the same time as performing the wafer processing step in the process chamber.

8. The method according to claim 6, further comprises guiding the plasma gas from the remote plasma source to the process chamber.

9. The method according to claim 6, wherein the plasma gas comprises an ozone gas or a fluorine gas.
